(19) United States
(12) Patent Application Publication
(10) Pub. No.: US 2016/0224151 A1
(43) Pub. Date: Aug. 4, 2016

(54) ELECTRODE TO BE USED IN INPUT DEVICE AND METHOD FOR PRODUCING SAME

(71) Applicants: KABUSHIKI KAISHA KOBE SEIKO SHO (KOBE STEEL, LTD.), Hyogo (JP); KOBELCO RESEARCH INSTITUTE, INC., Hyogo (JP)

(72) Inventors: Hiroshi GOTO, Hyogo (JP); Mototaka OCHI, Hyogo (JP); Yoko SHIDA, Hyogo (JP); Hiroyuki OKUNO, Hyogo (JP)

(73) Assignees: KABUSHIKI KAISHA KOBE SEIKO SHO (KOBE STEEL, LTD.), Kobe-shi, Hyogo (JP); KOBELCO RESEARCH INSTITUTE, INC., Kobe-shi, Hyogo (JP)

(21) Appl. No.: 14/917,450

(22) PCT Filed: Sep. 22, 2014
(86) PCT No.: PCT/JP2014/075146

§ 371 Date: Mar. 8, 2016

(30) Foreign Application Priority Data
Sep. 30, 2013 (JP) 2013-205502

(51) Int. Cl. G06F 3/044; G02F 1/1343; G02F 1/1333; C23C 14/00; C23C 14/06

(52) U.S. Cl. CPC G06F 3/044; C23C 14/0036; C23C 14/0641; G02F 1/13338; G02F 1/13439; G06F 2203/04103

(57) ABSTRACT

An electrode for use in an input device is formed on a transparent substrate. The electrode has a laminated structure including a first layer, a second layer and a third layer on one surface of the transparent substrate, in this order from the farthest side from the surface. The first layer includes a transparent conductive film. The second layer includes one or more members of a nitride of Mo and a nitride of an Mo alloy. The third layer includes a metal film having a reflectance of 40% or higher and a transmittance of 10% or less.

### TECHNICAL FIELD

The present invention relates to an electrode for use in input devices and a process for producing the electrode. Touch panel sensors are exemplified and explained below as a representative example of the input devices. However, the present invention is not limited thereto.

### BACKGROUND ART

Touch panel sensors are used by being adhered as input devices onto the display screen of display devices such as liquid-crystal display devices and organic EL devices. Touch panel sensors are easy to use and are hence used in the operation screens of ATMs of banks, ticket-vending machines, car navigation systems, PDAs (Personal Digital Assistants, mobile information device for personal use), copiers, etc. In recent years, they are used in a wide range of applications including cell phones and tablet personal computers (PCs). Methods of their input point detection include a resistance film type, a capacitance type, an optical type, an ultrasonic surface acoustic wave type, and a piezoelectric type. Among these, the capacitance method is preferably used in cell phones and tablet PCs because of the satisfactory responsiveness, low cost, and simple structure thereof, etc.

A touch panel sensor of the capacitance method has a structure in which two kinds of transparent conductive films are orthogonally disposed on a transparent substrate such as a glass substrate, and the surface thereof is covered by a cover (insulator) such as a protective glass. When the surface of the touch panel sensor having the configuration described above is touched with a finger, pen, or the like, the capacitance of the two transparent conductive films changes and the resultant change in the quantity of electric current flowing through the capacitance is detected by the sensor. Thus, the point having been touched can be ascertained.

As the transparent substrate used for a touch panel sensor having the configuration described above, use may be made of a substrate for exclusive use in touch panel sensors. However, transparent substrates used for display devices can also be used. Specifically, examples thereof include color filter substrates for use in liquid-crystal display devices and glass substrates for use in organic EL devices. Use of such transparent substrates for display devices makes it possible to accommodate properties required as touch panel sensors (e.g., an improvement in display contrast ratio, improvement in luminance, thickness reduction in smartphones, and the like).

In FIG. 2 is illustrated a diagrammatic cross-sectional view in which electrodes for touch panel sensors is mounted on the color filter substrate (CF substrate) of the liquid-crystal display device illustrated in FIG. 1. In FIG. 2, the electrodes are disposed in accordance with the pattern of the black matrix. Recently, investigations are being made on use of low-resistance metal electrodes as the electrode shown in FIG. 2, for improving the transmittance of the light from the backlight.

However, there is a problem in that since metal electrodes have a high reflectance, they can be seen by the user with the naked eye (they are visible), resulting in a decrease in contrast ratio. Because of this, in the case of using a metal electrode, a method is, for example, being employed in which the metal film is subjected to a blackening treatment to reduce the reflectance.

For example, Patent Document 1 describes a method in which in order to overcome the problem concerning the visibility of a bridge electrode for interconnecting conductive transparent pattern cells, a black conductive material is used to form a bridge electrode over an insulating layer formed on conductive pattern cells. Specifically, a method is exemplified therein, in which a metal such as Al, Au, Ag, Sn, Cr, Ni, Ti, or Mg is blackened by converting into an oxide, nitride, fluoride, or the like by reaction with a chemical. However, Patent Document 1 only describes a technique for reducing the reflectance of a bridge electrode by a blackening treatment of a metal, and a reduction in electrical resistivity is not taken into account at all. Because of this, the examples mentioned above involve materials having a high electrical resistivity, such as metal oxides, and cannot be applied to electrodes for low-electrical-resistivity wiring. Furthermore, Patent Document 1 includes substances which are highly reactive and dangerous, such as the nitride of Ag and the oxide of Mg, and is poor in practicability.

### PRIOR ART DOCUMENT

### Patent Document

### Patent Document 1: JP-A-2013-127792

### SUMMARY OF THE INVENTION

### Problems that the Invention is to Solve

The present invention has been achieved in view of the circumstances described above and an object thereof is to provide: a novel electrode which is for use in input devices represented, for example, by touch panel sensors of the capacitance type and which has a low electrical resistivity and a low reflectance; and a process for producing the same.

### Means for Solving the Problems

The electrode for use in input devices of the capacitance type, according to the present invention, which has overcome the problems described above, is an electrode formed on a transparent substrate, the electrode having a laminated structure including, in a following order from an opposite side to (a front side of) the transparent substrate, a first layer including a transparent conductive film, a second layer including one or more members of a nitride of Mo and a nitride of an Mo alloy, and a third layer including a metal film having a reflectance of 40% or higher and a transmittance of 10% or less.

In a preferred embodiment of the present invention, the metal film of the third layer contains one or more members of Mo and an Mo alloy.

In a preferred embodiment of the present invention, a fourth layer including a transparent conductive film is further included between the second layer and the third layer.

In a preferred embodiment of the present invention, a fifth layer including a metal film having a lower electrical resistivity than the third layer is further included between the transparent substrate and the third layer.

In a preferred embodiment of the present invention, the metal film of the fifth layer contains one or more members selected from the group consisting of Al, an Al alloy, Cu, a Cu alloy, Ag, and an Ag alloy.

In a preferred embodiment of the present invention, the second layer has a difference in a nitrogen content of the nitride between a front side thereof and a transparent-substrate side thereof.

In a preferred embodiment of the present invention, the transparent conductive film of the first layer includes one or more members of In and Zn.

In a preferred embodiment of the present invention, the Mo alloy of the second layer includes one or more members of Nb, W, Ti, V, and Cr.

In a preferred embodiment of the present invention, the transparent conductive film of the first layer has a thickness of 35 to 100 nm.

In a preferred embodiment of the present invention, the nitride of the second layer has a thickness of 5 to 80 nm.

In a preferred embodiment of the present invention, the metal film of the third layer has a thickness of 20 to 200 nm.

In a preferred embodiment of the present invention, the transparent conductive film of the fourth layer has a thickness of 6 to 100 nm.

The present invention further involves an input device having the electrode described in any one of the above.

In a preferred embodiment of the present invention, the input device is a touch panel sensor.

The process for producing an electrode according to the present invention, which has overcome the problems described above, includes depositing the nitride of the second layer by a reactive sputtering method that involves a nitrogen gas.

### Effects of the Invention

In the electrode of a laminated structure according to the present invention, since a metal film constituted of at least one member of a nitride of Mo and a nitride of an Mo alloy is used as the second layer, not only a low electrical resistivity inherent in metal films but also a low reflectance can be attained. Because of this, in the cases when the electrode of the present invention, which has the laminated structure including a transparent conductive film disposed on (on the front side of) the metal film (second layer) and further including a metal film (third layer) having given values of reflectance and transmittance and disposed under (on the transparent-substrate side of) the second layer, is used as an electrode for input devices, an input device equipped with the electrode is obtained in which a low electrical resistivity that has been unable to be attained with a transparent conductive film alone and a low reflectance that has been unable to be attained with a metal film alone are combined.

### BRIEF DESCRIPTION OF THE DRAWINGS

FIG. 1 is a diagrammatic cross-sectional view which schematically illustrates the configuration of a conventional liquid-crystal display device.

FIG. 2 is a diagrammatic cross-sectional view which schematically illustrates a structure in which an electrode for input devices is applied on a color filter substrate.

FIG. 3 is a diagrammatic cross-sectional view which schematically illustrates a configuration of the electrode according to the present invention (a three-layer structure composed of a first layer, a second layer, and a third layer in this order from the front side).

FIG. 4 is a diagrammatic cross-sectional view which schematically illustrates another configuration of the electrode according to the present invention (a four-layer structure composed of a first layer, a second layer, a fourth layer, and a third layer in this order from the front side).

FIG. 5 is a diagrammatic cross-sectional view which schematically illustrates another configuration of the electrode according to the present invention (a four-layer structure composed of a first layer, a second layer, a third layer, and a fifth layer in this order from the front side).

FIG. 6 is a diagrammatic cross-sectional view which schematically illustrates another configuration of the electrode according to the present invention (a five-layer structure composed of a first layer, a second layer, a fourth layer, a third layer, and a fifth layer in this order from the front side).

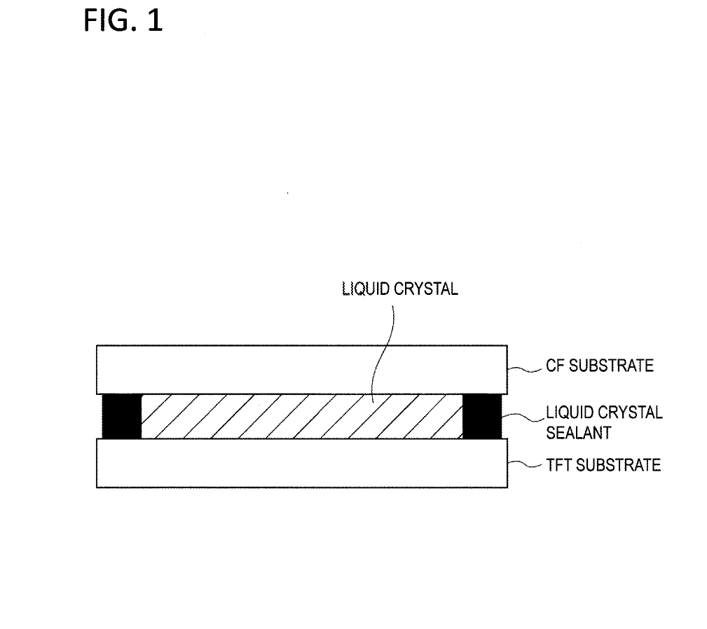

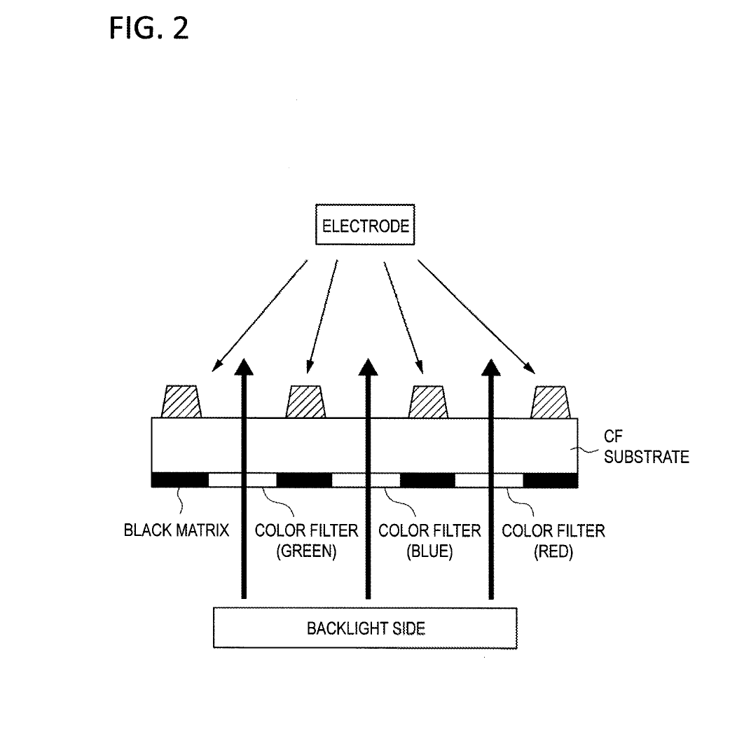

### MODES FOR CARRYING OUT THE INVENTION

The present inventors have diligently made investigations in order to provide an electrode for use in input devices which includes a metal film and has a low electrical resistivity and a low reflectance. As a result, it has been discovered that the desired purpose is achieved by using an electrode having a laminated structure which includes a first layer constituted of a transparent conductive film, a second layer constituted of at least one member of a nitride of Mo and a nitride of an Mo alloy, and a third layer constituted of a metal film having a reflectance of 40% or higher and a transmittance of 10% or less, in this order from the opposite side to (the front side of) the transparent substrate. The present invention has been thus completed.

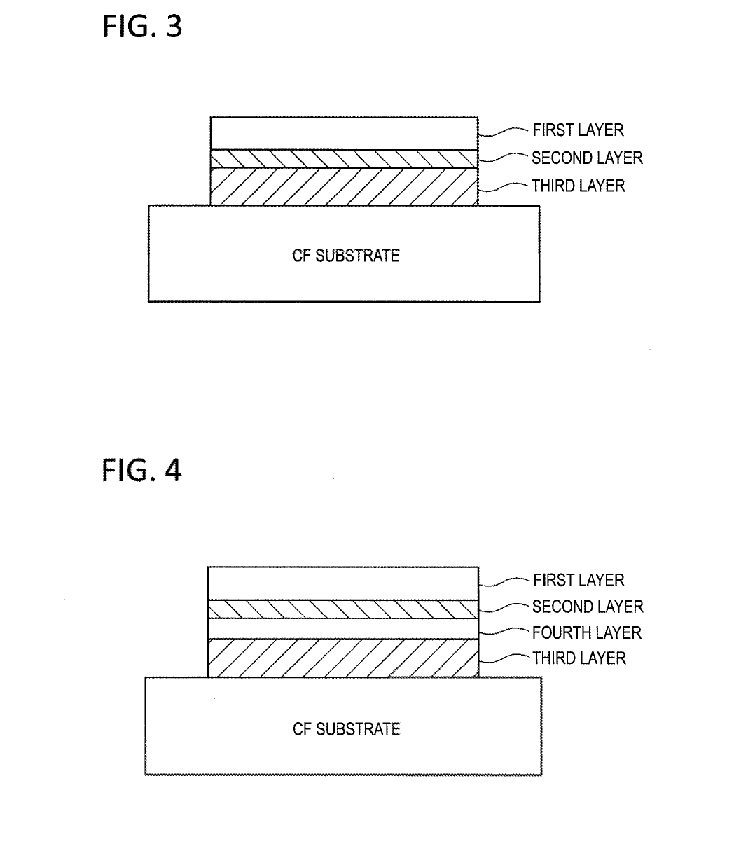

Preferred embodiments of the electrode according to the present invention are explained below in detail while referring to FIG. 3 to FIG. 6. However, the electrode of the present invention is not limited to these drawings. For example, although a CF substrate is used as the transparent substrate in FIG. 3 to FIG. 6 in view of application to liquid-crystal display devices, the transparent substrate is not limited thereto. In the case of using not liquid-crystal display devices but organic EL display devices, CF substrates are unnecessary in many cases and, hence, a glass substrate such as a cover glass can be used as the transparent substrate. The kind of transparent substrate for use in the present invention will be described later in detail.

### (1) First Embodiment

### Electrode of Three-Layer Structure Composed of First Layer to Third Layer

The electrode illustrated in FIG. 3 indicates the basic configuration of an electrode according to the present invention, and has a laminated structure (three-layer structure) including a first layer constituted of a transparent conductive film, a second layer constituted of at least one member of a nitride of Mo and a nitride of an Mo alloy, and a third layer constituted of a metal film having a reflectance of 40% or higher and a transmittance of 10% or less, in this order from the opposite side to (the front side of) the transparent substrate. The term “three-layer structure” herein means that it is configured of three layers in total, i.e., the first layer, the second layer and the third layer described above. For example, an embodiment thereof in which the second layer is configured of plural layers having two or more layers is also included in the “three-layer structure”, as will be described later. The same applies to the “four-layer structure” and “five-layer structure” which will be described later.

The first layer is constituted of a transparent conductive film. Thus, a low reflectance is obtained. The transparent conductive film is not particularly limited so long as it is in common use in the technical filed of the present invention. It is, however, preferable that at least one member of In and Zn is contained. For example, In—Zn—O, Zn—Al—O, Zn—O, In—O, and the like are more preferred when processability etc. are taken into account.

From the standpoint of effectively producing the low-reflectance effect of the formation of a transparent conductive film, it is preferable that the thickness of the first layer should be regulated to 35 nm or larger. More preferably, it is 45 nm or larger. However, in case where the thickness of the first layer exceeds 100 nm, there is a possibility of causing the reflectance increase and an etching residue. Consequently, 100 nm or less is preferred and 80 nm or less is more preferred.

The second layer is constituted of at least one member of a nitride of Mo and a nitride of an Mo alloy, and is a layer which most characterizes the present invention. Due to the use of the compound, the reflectance can be reduced, while a low electrical resistivity due to the use of the metallic material is being exhibited. In contrast, in case where an oxide of a metal is used as in Patent Document 1, an electrical resistivity increases even though the reflectance could be reduced. Attention was directed in the present invention especially to Mo among metal materials because of its excellence in not only a low electrical resistivity but also in processability by wet etching. Namely, by using a nitride of Mo or a nitride of an Mo alloy, characteristics of not only a low electrical resistivity and a low reflectance but also a high processability are exhibited.

In this description, the term “nitride” means that the Mo or the Mo alloy should contain at least nitrogen so that the desired effects are effectively exhibited, and this need not be a nitride which satisfies a stoichiometric composition. For example, in the case where the nitride of Mo is expressed by MoNₓ, x may be about 0.1-0.95.

It is preferable that the Mo alloy should contain at least one member of Nb, W, Ti, V, and Cr. Examples thereof include Mo—Nb alloys, Mo—W alloys, Mo—Ti alloys, Mo—V alloys, and Mo—Cr alloys. When processability by wet etching is taken into account, Mo—Nb alloys are more preferred.

It is preferable that the thickness of the second layer should be 5 nm or larger from the standpoint of low reflectance. More preferably, it is 10 nm or larger. However, in case where the thickness of the second layer exceeds 80 nm, there is a possibility that not only the reflectance might increase but also a decrease in production efficiency might result. Consequently, the thickness of the second layer is regulated to preferably 80 nm or less and more preferably 50 nm or less.

The second layer may be constituted of only one member or may be constituted of two or more members, so long as the requirements shown above are satisfied. Specifically, the second layer may be constituted only of a nitride of Mo (one member), or may be constituted only of a nitride of an Mo alloy (one member). Alternatively, the second layer may be constituted of a nitride of Mo and a nitride of an Mo alloy (two or more members). Alternatively, the second layer may be constituted of two or more Mo alloy nitrides differing in the kind of the Mo alloy.

Furthermore, the second layer may be constituted of a single layer or may be configured of plural layers having two or more layers, so long as the requirements shown above are satisfied. Examples of the plural layers include an embodiment in which plural kinds are laminated (for example, an embodiment in which a nitride of Mo and a nitride of an Mo—Nb alloy are laminated as two layers) and an embodiment in which substances which are of the same kind but differ in nitrogen content are laminated (for example, an embodiment in which nitride of an Mo—Nb alloy having a high nitrogen content and an Mo—Nb alloy having a low nitrogen content are laminated as two layers).

The nitrogen content in the second layer may be even or may be varied (namely, may have a concentration distribution) along the thickness direction of the second layer. It is preferable in the present invention that the second layer should have a difference in the nitrogen content between the front side thereof and the transparent-substrate side thereof. For example, by controlling the nitrogen content in the front side to be lower than the nitrogen content in the transparent-substrate side, the absorption of light can be enhanced (the reflectance can be reduced).

The third layer is constituted of a metal film having a reflectance of 40% or higher and a transmittance of 10% or less. The third layer is necessary for ensuring a desired low electrical resistivity in the laminated electrode structure. It is also necessary for preventing the light which has passed through the second layer from reaching the transparent substrate because the first layer and the second layer in the present invention both have a low reflectance. From this standpoint, it is necessary to dispose a metal film having a reflectance of 40% or higher and a transmittance of 10% or less. Lower transmittance is preferred and 5% or less is preferred. Because of this, for example, metal films having a high transmittance such as thin Ag films cannot be employed as the third layer in the present invention.

Examples of the metal film which satisfies the requirement include Mo, Mo alloys, Cr, and Cr alloys. As will be described later, the layers to constitute the electrode of the present invention are deposited preferably by sputtering. Because of this, when production efficiency and the like are taken into account, it is preferable that the third layer should be constituted of the same metal as the second layer (namely, at least one member of Mo and an Mo alloy). The kinds of Mo alloys which are preferably used as the third layer are the same as those for the second layer described above.

It is preferable that the thickness of the third layer should be 20 nm or larger from the standpoint of obtaining a low electrical resistivity. More preferably, it is 25 nm or larger. However, in case where the thickness of the third layer exceeds 200 nm, there is a possibility of a decrease in processability, warpage of the substrate, etc. Consequently, the thickness of the third layer is regulated to preferably 200 nm or less and more preferably 150 nm or less.

The transparent substrate to be used in the present invention is not particularly limited so long as it has transparency and is in common use in the technical field of the present invention. Examples thereof include glass substrates, film substrates and quarts substrates, which constitute color filter substrates or cover glasses.

Although the electrode of the present invention has a basic configuration of the three-layer structure composed of the first layer to the third layer, as described in (1) above, it may have a structure composed of, for example, four or more layers, for the purpose of further improving in desired low electrical resistivity and low reflectance. Preferred embodiments of the electrode of the present invention which has a structure composed of four or more layers are explained below. However, the present invention is not limited thereto.

### (2) Second Embodiment

### Electrode of Four-Layer Structure (Part 1)/Four-Layer Structure Composed of First Layer to Fourth Layer

The electrode illustrated in FIG. 4 is a preferred embodiment of the electrode according to the present invention. In the electrode of FIG. 3 described above, a fourth layer constituted of a transparent conductive film is interposed between the second layer and the third layer (four-layer structure). By interposing a transparent conductive film as the fourth layer, the reflectance is reduced further.

From the standpoint of effectively producing such effect of the fourth layer, it is preferred to regulate the thickness of the fourth layer to 6 nm or larger. More preferably, it is 10 nm or larger. However, in case where the thickness of the fourth layer exceeds 100 nm, there is a possibility of causing the reflectance increase and an etching residue. Consequently, the thickness of the fourth layer is regulated to preferably 100 nm or less and more preferably 80 nm or less.

The transparent conductive film of the fourth layer is the same as the first layer described in (1) above, and explanations thereon are omitted. The fourth layer and the first layer described above may be constituted of the same kind or may be constituted of different kinds so long as they are transparent conductive films.

The configurations (kind and preferred thickness) of the first layer to third layer, other than the fourth layer, are the same as in (1) above, and explanations thereon are omitted.

### (3) Third Embodiment

### Electrode of Four-Layer Structure (Part 2)/Four-Layer Structure Composed of First Layer to Third Layer and Fifth Layer

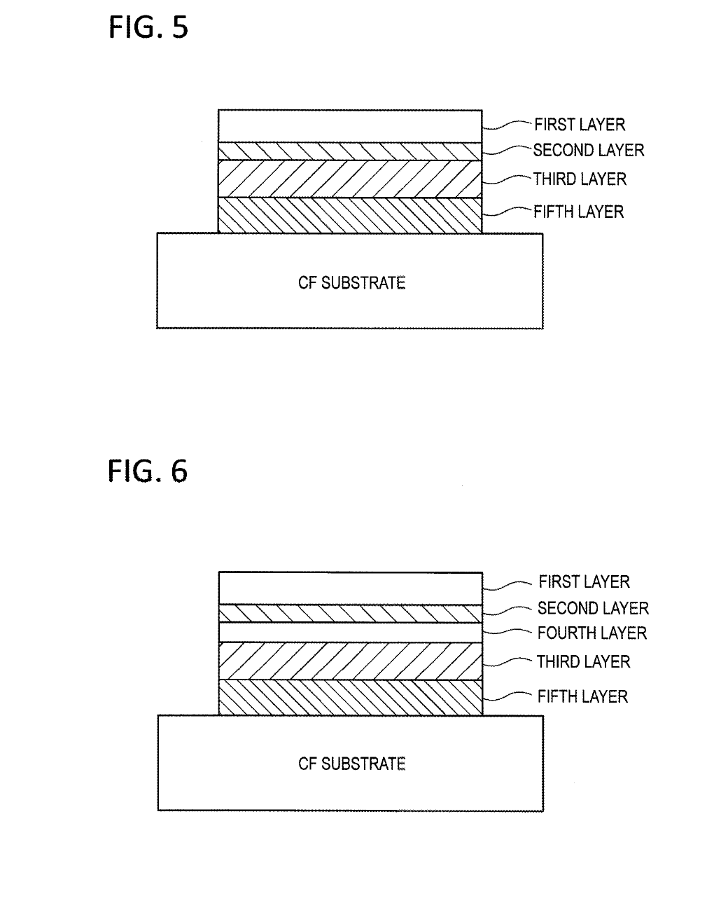

The electrode illustrated in FIG. 5 is another preferred embodiment of the electrode according to the present invention. In the electrode of FIG. 3 described above, a fifth layer constituted of a metal film having a lower electrical resistivity than the third layer is interposed between the third layer and the transparent substrate (CF substrate in FIG. 5) (four-layer structure). By interposing the metal film as the fifth layer, the electrical resistivity is reduced further.

It is preferable that the electrical resistivity of the metal film constituting the fifth layer should be not higher than the electrical resistivity of Mo (about 12 μΩ·cm). Examples of the kind of such metal film include Al, Al alloys (e.g., Al—Nd alloys and Al—Ni alloys), Cu, Cu alloys (e.g., Cu—Mn alloys and Cu—Ni alloys), Ag, and Ag alloys (e.g., Ag—Bi alloys, Ag—Pd alloys, and Ag—In alloys).

From the standpoint of effectively producing such effect of the fifth layer, it is preferred to regulate the thickness of the fifth layer to 50 nm or larger. More preferably, it is 100 nm or larger. However, in case where the thickness of the fifth layer exceeds 500 nm, there is a possibility of causing increased side etching, resulting in a decrease in processability, etc. Consequently, the thickness of the fifth layer is regulated to preferably 500 nm or less and more preferably 400 nm or less.

The configurations (kind and preferred thickness) of the first layer to third layer, other than the fifth layer, are the same as in (1) above, and explanations thereon are omitted.

### (4) Fourth Embodiment

### Electrode of Five-Layer Structure Composed of First Layer to Fifth Layer

The electrode illustrated in FIG. 6 is another preferred embodiment of the electrode according to the present invention. In the electrode of FIG. 3 described above, a fourth layer constituted of a transparent conductive film is interposed between the second layer and the third layer and further a fifth layer constituted of a metal film having a lower electrical resistivity than the third layer is interposed between the transparent substrate and the third layer (five-layer structure). By interposing both the transparent conductive film as the fourth layer, and the metal film having a low electrical resistivity as the fifth layer, the reflectance and electrical resistivity of the electrode are even more reduced.

The configuration (kind and preferred thickness) of the fourth layer is as describe in (2) above and the configuration (kind and preferred thickness) of the fifth layer is as described in (3) above, and explanations thereon are omitted. The configurations (kind and preferred thickness) of the first layer to third layer, other than the forth layer and the fifth layer, are the same as in (1) above, and explanations thereon are omitted.

The electrode of the present invention has been explained above in detail.

In this description, “electrode” includes wiring before processing into an electrode shape. Since the electrode of the present invention combines a low electrical resistivity and a low reflectance as described above, it can be applied to not only an electrode used in the input area of an input device but also to the wiring area disposed at the periphery of the panel by extending the electrode.

Examples of input devices to which the electrode of the present invention is applicable include both input devices which include a display device equipped with an input means, such as touch panels, and input devices having no display device, such as touch pads. Specifically, the electrode of the present invention can be used as an electrode of an input device which employs a combination of any of the various display devices described above with a position input means and in which a display on the screen is pushed to thereby operate apparatus; or an input device in which a display device separately disposed is operated in accordance with an input position on a position input means.

Next, a process for producing the electrode of the present invention is explained.

When an electrode having any of the laminated structures described above is produced, it is preferred to deposit the films by sputtering method by using sputtering targets, from the standpoints of line width reduction, homogenization of the alloy components within the film, ease of controlling the amount of an additive element, etc.

Especially for depositing the nitride (a nitride of Mo or a nitride of an Mo alloy) of the second layer, which characterizes the electrode of the present invention, it is preferable to employ a reactive sputtering method involving nitrogen gas from the standpoints of production efficiency, control of film quality, etc. Namely, a process for producing an electrode according to the present invention is characterized in that a nitride of Mo or a nitride of an Mo alloy, which constitutes the second layer, is deposited by a reactive sputtering method involving nitrogen gas.

Conditions for the reactive sputtering method for depositing the nitride of the second layer may be suitably controlled in accordance with, for example, the kind of the Mo alloy to be used, the layer of nitrogen to be introduced, etc. It is, however, preferred to be controlled as shown below.

Substrate temperature: room temperature to 400° C.

Film deposition temperature: room temperature to 400° C.

Atmosphere gas: nitrogen gas, Ar gas

Nitrogen gas flow rate during film deposition: 5 to 50% with respect to Ar gas

Sputtering power: 200 to 300 W

Ultimate vacuum: 1×10⁻⁶ Torr or less

In the case where the nitrogen content along the film thickness direction of the second layer is varied, this may be attained, for example, by changing the proportion of the Ar gas to the nitrogen gas.

As the sputtering target to be used, an Mo or Mo-alloy sputtering target according to the second layer to be deposited may be used. The shape of the sputtering target is not particularly limited, and use can be made of one which has been processed into any desired shape (e.g., a rectangular plate shape, circular plate shape, doughnut plate shape, or cylindrical shape) in accordance with the shape and structure of the sputtering device.

However, methods for depositing the second layer should not be limited to the method described above. For example, by using a sputtering target of Mo nitride or an Mo alloy nitride that has been nitrided beforehand, sputtering may be conducted in an atmosphere consisting only of a rare gas element such as Ar (without introducing nitrogen gas), to deposit the desired second layer.

The present invention is characterized by such method for depositing the second layer. As methods for depositing the other layers, methods in common use in the technical field of the present invention can be suitably employed.

It is presumed that, by the method described above, metal nitrides which have a diameter on the order of tens of nanometers to hundreds of micrometers are formed in the surface at intervals of about tens of nanometers or more and hundreds of nanometers or less in the metal (alloy) which is a main component as a matrix. Namely, by the method described above, it is thought that a low reflectance of the laminated electrode structure could be achieved by a self-organization means in the thin metal (alloy) film. Consequently, there is, for example, a merit in that use of a complicated and fine mold is unnecessary when the so-called moth eye structure or the like is formed by arranging cones on the surface of the thin electrode film at a period shorter than the wavelength of the incident light to obtain an antireflection effect.

### EXAMPLES

The present invention will be explained below in more detail by reference to Examples. However, the present invention is not limited by the following Examples, and can be modified to be performed within the scope adaptable to the gist described hereinabove and hereinafter, all of which are included in the technical range of the present invention.

### Example 1

In this Example, samples having the laminated structures (three-layer structure to five-layer structure) shown in Table 1 were produced by film deposition and examined for reflectance and electrical resistivity. The methods for depositing the fifth layer, the third layer, the fourth layer, the second layer, and the first layer in this order from the transparent-substrate side are explained below in the order. In the case where the corresponding layer did not exist (for example, No. 1 in Table 1 includes neither the fifth layer nor the fourth layer), the corresponding methods were omitted.

### (1) Production of Samples

### (1-1) Optional Deposition of Fifth Layer

First, a non-alkali glass plate (thickness, 0.7 mm; diameter, 4 inches) was used as a transparent substrate, and the metal film (fifth layer) shown in Table 1 was deposited on a surface thereof by the DC magnetron sputtering method. In the column “Fifth layer” in Table 1, “Al-2Nd” means an Al-2 at % Nd alloy. In the film deposition, the atmosphere within the chamber was temporarily regulated to an ultimate vacuum of 3×10⁻⁶ Torr prior to the film deposition. Thereafter, a disk-shaped sputtering target having a diameter of 4 inches and having the same component composition as the Al alloy film was used to conduct sputtering under the following conditions.

### (Sputtering Conditions)

Ar gas pressure: 2 mTorr

Ar gas flow rate: 30 sccm

Sputtering power: 260 W

Substrate temperature: room temperature

Film deposition temperature: room temperature

### (1-2) Deposition of Third Layer

Next, the Mo or Mo alloy film (third layer) shown in Table 1 was deposited by the DC magnetron sputtering method on the surface of the fifth layer (or on a surface of the transparent substrate in the case where the fifth layer had not been deposited). In the column “Third layer” in Table 1, “Mo-10Nb” means an Mo-10 at % Nb alloy. In the film deposition, the atmosphere within the chamber was temporarily regulated to an ultimate vacuum of 3×10⁻⁶ Torr prior to the film deposition. Thereafter, a disk-shaped sputtering target having a diameter of 4 inches and having the same component composition as each Mo or Mo alloy film was used to conduct sputtering under the following conditions.

### (Sputtering Conditions)

Ar gas pressure: 2 mTorr

Ar gas flow rate: 30 sccm

Sputtering power: 260 W

Substrate temperature: room temperature

Film deposition temperature: room temperature

### (1-3) Optional Deposition of Fourth Layer

A transparent conductive film as the fourth layer was optionally deposited on the third layer. In the case of a sample which did not include the fourth layer (e.g., No. 1 in Table 1), this film deposition was omitted.

Specifically, after the Mo or Mo alloy film was deposited as the third layer in the manner described above, a transparent conductive film (fourth layer) was subsequently deposited on the surface thereof by the DC magnetron sputtering method under the following sputtering conditions. In the deposition of the transparent conductive film, the atmosphere within the chamber was temporarily regulated to an ultimate vacuum of 3×10 Torr prior to the film deposition. Thereafter, a disk-shaped sputtering target having a diameter of 4 inches and having the same component composition as the transparent conductive film was used for processing.

### (Sputtering Conditions)

Ar gas flow rate: 30 sccm

O₂ gas flow rate: 0.8 sccm

Sputtering power: 260 W

Substrate temperature: room temperature

Film deposition temperature: room temperature

### (1-4) Deposition of Second Layer

The Mo nitride or Mo-alloy nitride (second layer) shown in Table 1 was subsequently deposited on the third layer (or on the fourth layer in the case where the fourth layer had been deposited) by the DC magnetron sputtering method under the following sputtering conditions. In this Example, the proportion of the Ar gas to the nitrogen gas during the deposition of the second layer was kept constant (the thickness-direction nitrogen content in the second layer is not varied and is even). In the column “Second layer” in Table 1, “Mo-10Nb-N” means a nitride of a Mo-10 at % Nb alloy. In the film deposition, the atmosphere within the chamber was temporarily regulated to an ultimate vacuum of 3×10⁻⁶ Torr prior to the film deposition. Thereafter, a disk-shaped sputtering target having a diameter of 4 inches and including Mo or an Mo alloy having the same composition as in the nitride was used to conduct sputtering by the reactive sputtering method.

### (Reactive Sputtering Conditions)

Ar gas flow rate: 26 sccm

N₂ gas flow rate: 4 sccm

Sputtering power: 260 W

Substrate temperature: room temperature

Film deposition temperature: room temperature

### (1-5) Deposition of First Layer

After the Mo nitride or Mo-alloy nitride was deposited as the second layer in the manner described above, a transparent conductive film (first layer) was subsequently deposited on the surface thereof by the DC magnetron sputtering method under the following sputtering conditions. In the deposition of the transparent conductive film, the atmosphere within the chamber was temporarily regulated to an ultimate vacuum of 3×10⁻⁶ Torr prior to the film deposition. Thereafter, a disk-shaped sputtering target having a diameter of 4 inches and having the same composition as the transparent conductive film was used to conduct sputtering under the following conditions.

### (Sputtering Conditions)

Ar gas flow rate: 8 sccm

O₂ gas flow rate: 0.8 sccm

Sputtering power: 260 W

Substrate temperature: room temperature

Film deposition temperature: room temperature

The laminated structures thus obtained were examined for reflectance and electrical resistivity in the following manners.

### (2) Measurement of Reflectance

As the reflectance, the visible light reflectance was measured with respect to light having wavelengths of 380 to 780 nm from illuminant D65 in accordance with JIS R 3106 by using a spectrophotometer (manufactured by JASCO Corporation, visible/ultraviolet spectrophotometer “V-570”). Specifically, the intensity of reflected light from the sample (measured value) to the intensity of reflected light from a reference mirror was calculated as “reflectance” (=[(intensity of reflected light from sample)/(intensity of reflected light from reference mirror)]×100%). In this Example, the reflectance of the sample was measured with respect to each of the wavelengths λ of 450 nm, 550 nm and 650 nm. The samples which had a reflectance of 30% or less at each wavelength were rated as acceptable (excellent in terms of low reflectance), and the samples which showed higher than 30% even at one of those were rated as unacceptable.

### (3) Measurement of Electrical Resistivity

A line-and-space pattern having a width of 10 μm was formed in the sample, and the electrical resistivity thereof was measured by the four-probe method. In this Example, the samples which had an electrical resistivity of 50 μΩ·cm or less were rated as acceptable (excellent in terms of low electrical resistivity), and the samples which showed higher than 50 μΩ·cm were rated as unacceptable.

The results of these are also shown in Table 1. In Table 1, the metal films shown in the column “Third layer” each satisfy the requirement “having a reflectance of 40% or higher and a transmittance of 10% or less” specified in the present invention. The metal film (Al—Nd alloy film of No. 18) shown in the column “Fifth layer” in Table 1 satisfies the requirement “having a lower electrical resistivity than the third layer (Mo film in No. 18)” specified in the present invention.

TABLE 1

| | First | Second | Third | Fourth | Fifth | | | | | Electrical |
|---|---|---|---|---|---|---|---|---|---|---|
| | layer | layer | layer | layer | layer | Reflectance (%) | | | | resistivity |
| No. | (thickness) | (thickness) | (thickness) | (thickness) | (thickness) | Evaluation | 450 nm | 550 nm | 650 nm | (μΩ · cm) |
| 1 | ITO | Mo—N | Mo | none | none | acceptable | 25% | 12% | 12% | acceptable |
| | 60 nm | 15 nm | 60 nm | | | | | | | |
| 2 | IZO | Mo—N | Mo | none | none | acceptable | 29% | 10% | 20% | acceptable |
| | 60 nm | 15 nm | 60 nm | | | | | | | |
| 3 | AZO | Mo—N | Mo | none | none | acceptable | 20% | 16% | 19% | acceptable |
| | 60 nm | 15 nm | 60 nm | | | | | | | |
| 4 | ITO | Mo—10Nb—N | Mo—10Nb | none | none | acceptable | 23% | 12% | 11% | acceptable |
| | 60 nm | 15 nm | 60 nm | | | | | | | |
| 5 | ITO | Mo—50Ti—N | Mo—50Ti | none | none | acceptable | 29% | 21% | 28% | acceptable |
| | 60 nm | 15 nm | 60 nm | | | | | | | |
| 6 | ITO | Mo—10Cr—N | Mo—10Cr | none | none | acceptable | 21% | 10% | 12% | acceptable |
| | 60 nm | 15 nm | 60 nm | | | | | | | |
| 7 | ITO | Mo—10V—N | M—10Cr | none | none | acceptable | 21% | 10% | 12% | acceptable |
| | 60 nm | 15 nm | 60 nm | | | | | | | |
| 8 | ITO | Mo—10Nb—N | Mo | none | none | acceptable | 24% | 12% | 11% | acceptable |
| | 60 nm | 15 nm | 60 nm | | | | | | | |
| 9 | ITO | Mo—N | Mo | none | none | acceptable | 10% | 18% | 30% | acceptable |
| | 35 nm | 15 nm | 60 nm | | | | | | | |
| 10 | ITO | Mo—N | Mo | none | none | acceptable | 30% | 21% | 10% | acceptable |
| | 100 nm | 15 nm | 60 nm | | | | | | | |
| 11 | ITO | Mo—N | Mo | none | none | acceptable | 30% | 11% | 13% | acceptable |
| | 60 nm | 5 nm | 60 nm | | | | | | | |
| 12 | ITO | Mo—N | Mo | none | none | acceptable | 30% | 8% | 9% | acceptable |
| | 60 nm | 80 nm | 60 nm | | | | | | | |
| 13 | ITO | Mo—N | Mo | none | none | acceptable | 30% | 12% | 13% | acceptable |
| | 60 nm | 15 nm | 20 nm | | | | | | | |
| 14 | ITO | Mo—N | Mo | none | none | acceptable | 23% | 12% | 12% | acceptable |
| | 60 nm | 15 nm | 200 nm | | | | | | | |
| 15 | ITO | Mo—N | Mo | ITO | none | acceptable | 20% | 6% | 5% | acceptable |
| | 60 nm | 15 nm | 60 nm | 10 nm | | | | | | |
| 16 | ITO | Mo—N | Mo | ITO | none | acceptable | 10% | 1% | 5% | acceptable |
| | 60 nm | 15 nm | 60 nm | 60 nm | | | | | | |
| 17 | ITO | Mo—N | Mo | ITO | none | acceptable | 30% | 12% | 16% | acceptable |
| | 60 nm | 15 nm | 60 nm | 100 nm | | | | | | |
| 18 | ITO | Mo—N | Mo | none | Al—2Nd | acceptable | 25% | 12% | 12% | acceptable |
| | 60 nm | 15 nm | 30 nm | | 100 nm | | | | | |
| 19 | ITO | Mo—N | Mo | none | none | unacceptable | 38% | 45% | 49% | acceptable |
| | 15 nm | 15 nm | 60 nm | | | | | | | |
| 20 | ITO | Mo—N | Mo | none | none | unacceptable | 33% | 10% | 11% | acceptable |
| | 60 nm | 2 nm | 60 nm | | | | | | | |
| 21 | ITO | Mo—N | Mo | none | none | unacceptable | 31% | 8% | 10% | acceptable |
| | 60 nm | 100 nm | 60 nm | | | | | | | |
| 22 | ITO | Mo—N | Mo | none | none | acceptable | 28% | 8% | 11% | unacceptable |
| | 60 nm | 15 nm | 10 nm | | | | | | | |
| 23 | ITO | Al—N | Mo | none | none | unacceptable | 45% | 25% | 11% | unacceptable |
| | 60 nm | 15 nm | 60 nm | | | | | | | |

No. 1 to No. 18 in Table 1 are each an example of the present invention which satisfies the requirements according to the present invention, and were able to suppress both the reflectance and the electrical resistivity low.

In contrast, No. 19 to No. 23 in Table 1 have the following drawbacks.

In No. 19, the thickness of the first layer (transparent conductive film) was too small below the preferred lower limit according to the present invention. The given low reflectance was hence not obtained.

In No. 20, the thickness of the second layer (nitride of Mo/nitride of Mo alloy) was too small below the preferred lower limit according to the present invention, and the given low reflectance was hence not obtained therein also. Meanwhile, in No. 21, the thickness of the second layer was too large beyond the preferred upper limit according to the present invention, and the given low reflectance was hence not obtained.

In No. 22, the thickness of the third layer (Mo/Mo alloy) was too small below the preferred lower limit according to the present invention, and the given low resistivity was hence not obtained.

No. 23 is an example in which the second layer is constituted of an Al—N alloy and does not satisfy the requirement according to the present invention, in which both the reflectance and the electrical resistivity were increased.

While the present invention has been described in detail and with reference to specific embodiments thereof, it will be apparent to one skilled in the art that various changes and modifications can be made therein without departing from the spirit and scope of the present invention.

This application is based on a Japanese patent application filed on Sep. 30, 2013 (Application No. 2013-205502), the contents thereof being incorporated herein by reference.

### INDUSTRIAL APPLICABILITY

The present invention is useful in touch panel sensors for use as the input devices of liquid-crystal display devices, organic EL devices, etc., and can attain reduction in electrical resistivity and reduction in reflectance.

1. An electrode which is formed on a transparent substrate, having a laminated structure comprising, on one surface of the transparent substrate, in a following order from the farthest side from the surface:
a first layer comprising a transparent conductive film;
a second layer comprising one or more members of a nitride of Mo and a nitride of an Mo alloy; and
a third layer comprising a metal film having a reflectance of 40% or higher and a transmittance of 10% or less.

2. The electrode according to claim 1, wherein the metal
film of the third layer comprises one or more members selected from the group consisting of Mo and an Mo alloy.

3. The electrode according to claim 1, further comprising a fourth layer comprising a transparent conductive film, between the second layer and the third layer.

4. The electrode according to claim 1, further comprising a fifth layer comprising a metal film having a lower electrical resistivity than the third layer, between the transparent substrate and the third layer.

5. The electrode according to claim 4, wherein the metal film of the fifth layer comprises one or more members selected from the group consisting of Al, an Al alloy, Cu, a Cu alloy, Ag, and an Ag alloy.

6. The electrode according to claim 1, wherein the second layer has a difference in a nitrogen content of the nitride between a front side thereof and a transparent-substrate side thereof.

7. The electrode according to claim 1, wherein the transparent conductive film of the first layer comprises one or more members selected from the group consisting of In and Zn.

8. The electrode according to claim 1, wherein the Mo alloy of the second layer comprises one or more members selected from the group consisting of Nb, W, Ti, V, and Cr.

9. An input device comprising the electrode described in claim 1.

10. A touch panel sensor comprising the electrode described in claim 1.

11. A process for producing the electrode described in claim 1, comprising:
depositing the nitride of the second layer by reactive sputtering using a target comprising Mo or an Mo alloy in an atmosphere of a nitrogen gas, or
depositing the nitride of the second layer by reactive sputtering using a target comprising a nitride of Mo or a nitride of an Mo alloy in an atmosphere of a gas containing no nitrogen.
